(19) United States
(12) Patent Application Publication
(10) Pub. No.: US 2009/0170280 A1
(43) Pub. Date: Jul. 2, 2009

(54) Method of Forming Isolation Layer of Semiconductor Device

(75) Inventor: Bo Min Park, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/163,400

(22) Filed: Jun. 27, 2008

(30) Foreign Application Priority Data
Dec. 27, 2007 (KR) 2007-138815

(51) Int. Cl. H01L 21/762

(52) U.S. Cl. 438/425; 257/E21.545

(57) ABSTRACT

A method of forming isolation layers of a semiconductor device, comprising providing a semiconductor substrate in which a tunnel dielectric layer and a conductive layer are formed in active regions having two ends and trenches are formed in isolation regions; rounding both ends of each active region by performing an O₂ plasma process on the semiconductor substrate; forming a first insulating layer on sidewalls of each trench; and, forming a second insulating layer, preferably having a greater fluidity than that of the first insulating layer, on the first insulating layer.

### CROSS-REFERENCE TO RELATED APPLICATION

Priority to Korean patent application number 10-2007-0138815, filed on Dec. 27, 2007, the disclosure of which is incorporated by reference in its entirety, is claimed.

### BACKGROUND OF THE INVENTION

The invention relates generally to a method of forming isolation layers of a semiconductor device and, more particularly, to a method of forming isolation layers of a semiconductor device, which can form the isolation layers in an isolation region of a substrate by employing a shallow trench isolation (STI) process.

Generally, a semiconductor device formed in a silicon wafer includes isolation regions for electrically isolating semiconductor elements. In particular, with the high degree of integration and miniaturization of semiconductor devices, active research has been done on size reduction of individual elements and also of the isolation region, since the process of forming the isolation regions is an initial process step of the entire manufacturing steps and greatly decides the size of an active region and process margin of post-process steps.

A field oxide layer is formed in this isolation region by a typical method, such as local oxidation of silicon (LOCOS) or profiled grove isolation (PGI), so that the active region is defined. In the LOCOS method, a nitride layer, i.e., an oxidization-prevention mask to define the active region is formed on a semiconductor substrate and then patterned to thereby expose some of the semiconductor substrate. The exposed semiconductor substrate is then oxidized to form the field oxide layer that is used as the isolation region. The LOCOS method is advantageous in that the process is simple, and wide and narrow portions can be separated at the same time. However, the LOCOS method is disadvantageous in that a bird's beak occurs due to lateral oxidization, which as a result widens the isolation region, and the sizes of the effective areas of source/drain regions can be reduced. The LOCOS method is also disadvantageous in that crystalline defects are generated in the silicon substrate because stress due to a difference in the coefficient of thermal expansion is concentrated on the corners of the oxide layer when the field oxide layer is formed and, therefore, the leakage current is large. Further, with the trend to a high degree integration of semiconductor devices, the design rule decreases and, therefore, the respective sizes of a semiconductor element and an isolation layer for isolating the semiconductor elements are reduced proportionately. Accordingly, typical isolation methods, such as LOCOS, have reached their limits.

A Shallow Trench Isolation (STI) method for solving the above problems is described below. First, a nitride layer having an etch selectivity different from that of a semiconductor substrate is formed on the semiconductor substrate. In order to use the nitride layer as a hard mask pattern, the nitride layer is patterned to form a nitride layer pattern. Trenches are formed by etching the semiconductor substrate to a specific depth using an etch process employing the nitride layer pattern. The trenches are gap-filled with an oxide layer. Here, since it is difficult to gap-fill the trenches at once, the gap-fill process is performed twice or more repeatedly in order to fully gap-fill the trenches. Next, isolation layers to gap-fill the trenches by performing chemical mechanical polishing (CMP).

However, in general, after the trenches are formed, each of two ends of a tunnel dielectric layer remaining in the active region has a pointed edge portion. If each of the ends of the tunnel dielectric layer has the pointed edge shape, mechanical stress and electrical stress can be concentrated on the both ends of the tunnel dielectric layer, having a significant influence on the characteristics of a semiconductor device.

### BRIEF SUMMARY OF THE INVENTION

The invention is directed to prevent mechanical stress and electrical stress from being concentrated on both ends of a tunnel dielectric layer by making each of the both ends of the tunnel dielectric layer, having a pointed profile, a round profile through an O₂ plasma process.

According to an aspect of the invention, a method of forming isolation layers of a semiconductor device comprises providing a semiconductor substrate comprising active regions and isolation regions, each active region having two ends, wherein a tunnel dielectric layer and a conductive layer are sequentially formed in the active regions and trenches are formed in the isolation regions, each trench defining sidewalls; performing an O₂ plasma process on the semiconductor substrate to round both ends of each active region; forming a first insulating layer on the sidewalls of each trench; and forming a second insulating layer, having a greater fluidity than that of the first insulating layer, on the first insulating layer.

The O₂ plasma process is preferably performed in a high-density plasma chemical vapor deposition (HDP-CVD) apparatus. The O₂ plasma process is preferably performed at a temperature in the range of 300 degrees Celsius to 500 degrees Celsius. The O₂ plasma process is preferably performed for 30 seconds to 3 minutes. A high-density plasma (HDP) oxide layer is preferably further formed on the sidewalls of a trench during the O₂ plasma process. The HDP oxide layer is preferably formed to a thickness of 100 angstroms to 300 angstroms. The first insulating layer preferably comprises a low-pressure tetra ethyl ortho silicate layer (LP-TEOS). A thickness of the first insulating layer, which can be close to or adjacent the tunnel dielectric layer, preferably ranges from 50 angstroms to 150 angstroms. The second insulating layer preferably comprises a spin on dielectric (SOD) layer. The second insulating layer highly preferably comprises polysilazane (PSZ) or hydrogen silsesquioxane (HSQ) material. The second insulating layer is preferably formed to a thickness of 3000 angstroms to 8000 angstroms. A thermal treatment process is preferably further performed on the second insulating layer. The thermal treatment process is preferably performed at a temperature in a range of 200 degrees Celsius to 800 degrees Celsius for 15 seconds to 120 minutes. Before the first insulating layer is formed, a wall oxide layer is preferably formed on the sidewalls of the trenches.

### BRIEF DESCRIPTION OF THE DRAWINGS

FIGS. 1A to 1F are cross-sectional views a method of forming isolation layers of a semiconductor device in accordance with the invention; and

FIG. 2A is a scanning electron microscope (SEM) photograph showing the cross section of a semiconductor device before an O₂ plasma process is performed; and

FIG. 2B is a SEM photograph showing the cross section of a semiconductor device after an O₂ plasma process is performed.

### DESCRIPTION OF SPECIFIC EMBODIMENT

A specific embodiment according to the invention is described below with reference to the accompanying drawings. However, the invention is not limited to the disclosed embodiment, but may be implemented in various ways. The embodiment is provided to complete the disclosure of the invention and to allow those having ordinary skill in the art to understand the scope of the invention. The scope of the invention is defined by the claims.

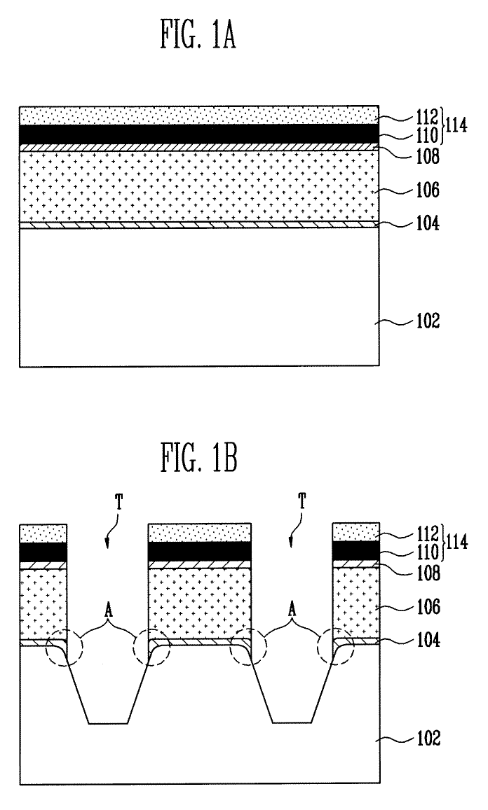

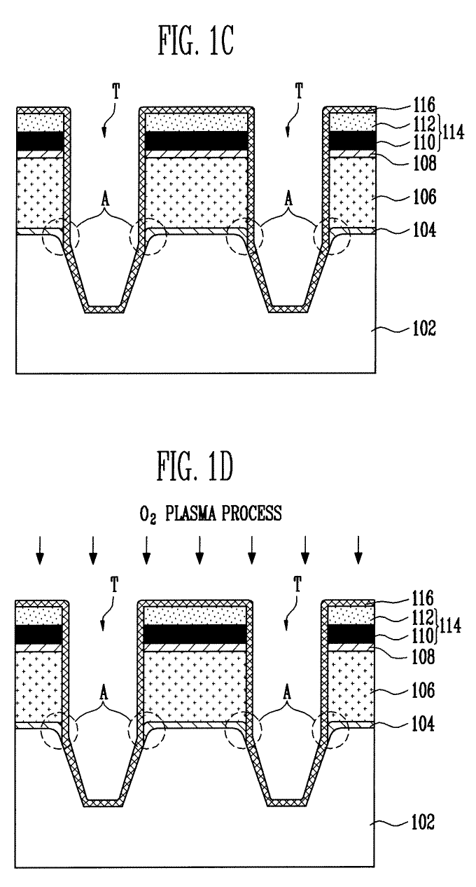

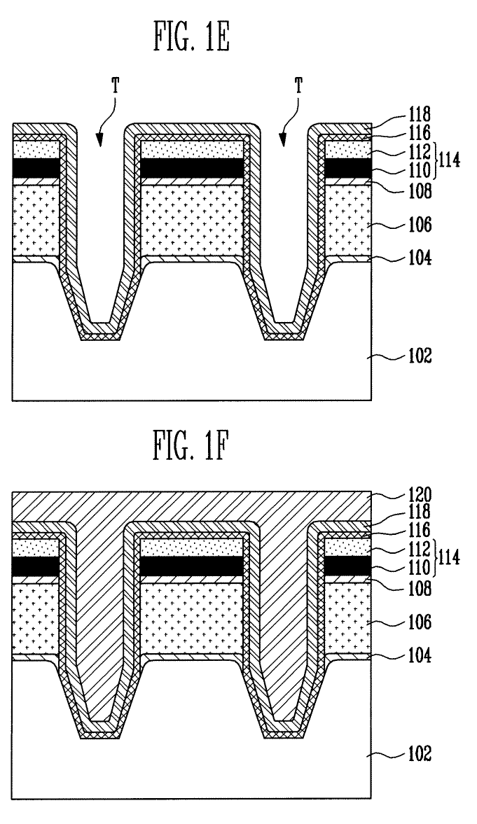

FIGS. 1A to 1F are cross-sectional views a method of forming isolation layers of a semiconductor device in accordance with the invention.

Referring to FIG. 1A, a screen oxide layer (not shown) is formed on a semiconductor substrate 102. A well ion implantation process or a threshold voltage ion implantation process is performed on the semiconductor substrate 102. The well ion implantation process is performed to form a well region in the semiconductor substrate 102. The threshold voltage ion implantation process is performed to control the threshold voltage of a semiconductor element such as a transistor. Here, the screen oxide layer (not shown) functions to prevent damage to the surface of the semiconductor substrate 102 when the well ion implantation process or the threshold voltage ion implantation process is carried out. Thus, the well region (not shown) is formed in the semiconductor substrate 102 and the well region can be formed in a triple structure.

After the screen oxide layer (not shown) is removed, a tunnel dielectric layer 104 is formed over the semiconductor substrate 102 in order to fabricate a NAND flash device, for example. The tunnel dielectric layer 104 can have electrons to pass therethrough by Fowler/Nordheim (F/N) tunneling. At the time of a program operation, electrons migrate from a channel region under the tunnel dielectric layer 104 to a floating gate on the tunnel dielectric layer 104, and at the time of an erase operation, electrons can migrate from the floating gate to the channel region under the tunnel dielectric layer 104. The tunnel dielectric layer 104 is preferably an oxide layer.

A conductive layer 106 for a floating gate is formed on the tunnel dielectric layer 104. The conductive layer 106 can trap electrons at the time of a program operation or discharge charges, trapped at the conductive layer 106, at the time of an erase operation. The conductive layer 106 is preferably formed from polysilicon.

A buffer layer 108 is formed on the conductive layer 106. A hard mask 114 is formed on the buffer layer 108. The buffer layer 108 is preferably an oxide layer. The hard mask 114 is preferably formed by stacking materials with different etch selectivities, for example, a nitride layer 110 for the hard mask and an oxide layer 112 for the hard mask.

Referring to FIG. 1B, a photoresist pattern (not shown) is formed on the hard mask 114 so that an isolation region is opened through the photoresist pattern. The hard mask 114, the buffer layer 108, the conductive layer 106, and the tunnel dielectric layer 104 are patterned by an etch process employing the photoresist pattern (not shown). The isolation region of the exposed semiconductor substrate 102 is etched to thereby form trenches T having a downward tapered shape. Thus, an active region is defined between the trenches T.

Meanwhile, each of both ends (indicated by ‘A’) of the active region has a pointed edge portion. However, if each end (indicated by ‘A’) of the active region has the pointed edge portion, mechanical stress and electrical stress can be concentrated on the both ends (indicated by ‘A’) of the active region when cycling and retention tests for reliability verification are performed after the manufacturing process of a semiconductor device is completed. To solve this problem, a process of making round each end (indicated by ‘A’) of the active region is performed subsequently.

Referring to FIG. 1C, in order to repair the sidewalls of the trenches which have been damaged in the etch process of forming the trenches, a wall oxide layer 116 is formed on the trench sidewalls.

Referring to FIG. 1 D, the both ends (indicated by ‘A’) of the active region are formed in a round profile. For this purpose, an O₂ plasma process is performed on the semiconductor substrate 102 including the both ends (indicated by ‘A’) of the active region. If the O₂ plasma process is carried out, oxidization of the both ends (indicated by ‘A’) of the active region, which have high energy and are influenced by plasma most greatly due to the pointed profile, is accelerated, so that the both ends (indicated by ‘A’) of the active region can be formed in a round profile. Accordingly, after the manufacturing process of a semiconductor device is completed, a problem that stress and electrical stress is concentrated on the both ends (indicated by ‘A’) of the active region when a test for reliability verification is carried out can be solved. Further, since the thickness of each of the both ends of the tunnel dielectric layer 104 is increased, leakage current at the both ends of the tunnel dielectric layer 104 can be reduced.

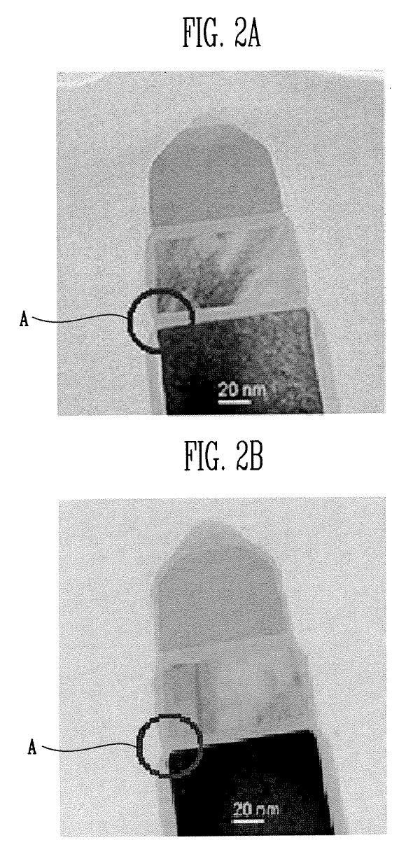

FIG. 2A is a scanning electron microscope (SEM) photograph showing the cross section of a semiconductor device before an O₂ plasma process is performed. FIG. 2B is a SEM photograph showing the cross section of a semiconductor device after an O₂ plasma process is performed. From FIGS. 2A and 2B, it can be seen that, after the O₂ plasma process is carried out, the both ends (indicated by ‘A’) of the active region are formed in a round profile.

The O₂ plasma process is preferably performed by supplying O₂ gas using a high-density plasma chemical vapor deposition (HDP-CVD) apparatus in a temperature range of 300 degrees Celsius to 500 degrees Celsius for 30 seconds to 3 minutes. However, SiH₄ gas that is typically supplied when forming a HDP oxide layer is not supplied. As described above, the O₂ plasma process is preferably performed at a relatively low temperature, so the influence on the oxide layers formed in the above process can be minimized. That is, at the time of the O₂ plasma process, the thickening thickness of the wall oxide layer 116 can be minimized about several to several tens of angstroms. Accordingly, any difficulty, which may occur when the trenches T are gap-filled with a liner insulating layer, etc. in a subsequent process, can be minimized and degradation of the tunnel dielectric layer 104 can also be minimized.

Meanwhile, although not shown in the drawings, at the time of the O₂ plasma process, the HDP oxide layer (not shown) is preferably formed in-situ on the sidewalls of the trenches T to a thickness of 100 angstroms to 300 angstroms.

Referring to FIG. 1E, a liner oxide layer 118 is formed on the wall oxide layer 116 including the trenches T. The liner oxide layer 118 functions as a barrier layer for outgassing and the preclusion of movement of dose ions when a thermal treatment process is performed on a spin on dielectric (SOD) layer formed in a subsequent process, thereby preventing device characteristics from degrading. The liner oxide layer 118 preferably comprises a low-pressure tetra ethyl ortho silicate layer (LP-TEOS). The LP-TEOS layer has excellent step coverage of about 65% and therefore can be easily formed along the sidewalls of the trenches T at a relatively low temperature. Thus, it can prevent the tunnel dielectric layer 104 from being degraded. The liner oxide layer 118 can be formed to a thickness which can maintain the shape of the trenches T, but can be formed to a thickness enough to serve as the barrier layer. In particular, a thickness of the liner oxide layer 118, which is close to the tunnel dielectric layer 104, preferably ranges from 50 angstroms to 150 angstroms.

Referring to FIG. 1F, an insulating layer 120 is formed on the liner oxide layer 118, thus gap-filling the trenches. The insulating layer 120 is liquefied and has a good fluidity, and therefore can be formed using a spin on dielectric (SOD) layer which can easily gap-fill the trenches. The insulating layer 120 is preferably formed to a thickness of 3000 angstroms to 8000 angstrom using polysilazane (PSZ)-based or hydrogen silsesquioxane (HSQ)-based materials.

In order to densify the film quality of the insulating layer 120 by discharging gas included in the insulating layer 120, thermal treatment is preferably performed on the insulating layer 120. The thermal treatment process is preferably performed at a temperature in a range of 200 degrees Celsius to 800 degrees Celsius for 15 seconds to 120 minutes.

Thereafter, although not shown in the drawings, a polishing process is performed on a surface of the insulating layer 120 and the liner insulating layer 118 so that the insulating layer remains only in the trenches, thus forming isolation layers within the trenches.

According to the method of forming isolation layers of a semiconductor device in accordance with the invention, both ends of a tunnel dielectric layer can be formed to have a round profile. Accordingly, mechanical stress and electrical stress are not concentrated on the both ends of the tunnel dielectric layer. Further, since a thickness of each of the both ends of the tunnel dielectric layer is increased, current leaked from both ends of the tunnel dielectric layer can be reduced.

The embodiment disclosed herein has been proposed to allow a person skilled in the art to easily implement the invention, and the person skilled in the part may implement the invention in various ways. Therefore, the scope of the invention is not limited by or to the embodiment as described above, and should be construed to be defined only by the appended claims and their equivalents.

What is claimed is:

1. A method of forming isolation layers of a semiconductor device, comprising:
providing a semiconductor substrate comprising active regions and isolation regions, each active region having two ends, wherein a tunnel dielectric layer and a conductive layer are sequentially formed in the active regions and trenches are formed in the isolation regions, each trench defining sidewalls;
performing an O₂ plasma process on the semiconductor substrate to round both ends of each active region;
forming a first insulating layer on the sidewalls of each trench; and
forming a second insulating layer, having a greater fluidity than that of the first insulating layer, on the first insulating layer.

2. The method of claim 1, comprising performing the O₂ plasma process in a high-density plasma chemical vapor deposition (HDP-CVD) apparatus.

3. The method of claim 1, comprising performing the O₂ plasma process at a temperature in the range of 300 degrees Celsius to 500 degrees Celsius.

4. The method of claim 1, comprising performing the O₂ plasma process for 30 seconds to 3 minutes.

5. The method of claim 1, further comprising forming a high-density plasma (HDP) oxide layer on the sidewall of a trench during the O₂ plasma process.

6. The method of claim 5, comprising forming the HDP oxide layer to a thickness of 100 angstroms to 300 angstroms.

7. The method of claim 1, wherein the first insulating layer comprises a low-pressure tetra ethyl ortho silicate layer (LP-TEOS).

8. The method of claim 1, wherein a thickness of the first insulating layer adjacent the tunnel dielectric layer ranges from 50 angstroms to 150 angstroms.

9. The method of claim 1, wherein the second insulating layer comprises a spin on dielectric (SOD) layer.

10. The method of claim 1, wherein the second insulating layer comprises polysilazane (PSZ) or hydrogen silsesquioxane (HSQ) material.

11. The method of claim 1, comprising forming the second insulating layer to a thickness of 3000 angstroms to 8000 angstroms.

12. The method of claim 1, further comprising performing a thermal treatment process on the second insulating layer.

13. The method of claim 12, comprising performing the thermal treatment process at a temperature in the range of 200 degrees Celsius to 800 degrees Celsius for 15 seconds to 120 minutes.

14. The method of claim 1, further comprising, before forming the first insulating layer, forming a wall oxide layer on the sidewalls of the trenches.
